(19) United States
(12) Patent Application Publication
(10) Pub. No.: US 2017/0374742 A1
(43) Pub. Date: Dec. 28, 2017

(54) COMPOSITE WIRING BOARD AND METHOD FOR MANUFACTURING COMPOSITE WIRING BOARD

(71) Applicant: IBIDEN CO., LTD., Ogaki (JP)

(72) Inventors: Takahisa HIRASAWA, Ogaki-shi (JP); Takayuki FURUNO, Ogaki-shi (JP); Kiyotaka TSUKADA, Ibi-gun (JP)

(73) Assignee: IBIDEN CO., LTD., Ogaki (JP)

(21) Appl. No.: 15/629,777

(22) Filed: Jun. 22, 2017

(30) Foreign Application Priority Data
Jun. 22, 2016 (JP) 2016-123704

(51) Int. Cl. H05K 1/14; H05K 3/46; H05K 3/36

(52) U.S. Cl. CPC H05K 1/148; H05K 3/4691; H01L 2224/16221; H05K 3/361; H05K 3/4617; H05K 3/4614

(57) ABSTRACT

A composite wiring board includes a first wiring board including a first insulating layer, a first conductor layer formed on the first insulating layer, and metal elements penetrating the first insulating layer and the first conductor layer such that the metal elements are electrically connected to each other by the first conductor layer, and a second wiring board including a second insulating layer and a second conductor layer forming on the second insulating layer and including metal connection terminals such that the metal connection terminals are corresponding to and directly bonded to the metal elements of the first wiring board, respectively.

### CROSS-REFERENCE TO RELATED APPLICATIONS

The present application is based upon and claims the benefit of priority to Japanese Patent Application No. 2016-123704, filed Jun. 22, 2016, the entire contents of which are incorporated herein by reference.

### BACKGROUND OF THE INVENTION

### Field of the Invention

The present invention relates to a composite wiring board and a method for manufacturing the composite wiring board.

### Description of Background Art

Japanese Patent Laid-Open Publication No. 2004-266236 describes that, in a composite wiring board that includes a rigid wiring board and a flexible wiring board, the rigid wiring board and the flexible wiring board are electrically and mechanically connected using an anisotropic conductive film. The entire contents of this publication are incorporated herein by reference.

### SUMMARY OF THE INVENTION

According to one aspect of the present invention, a composite wiring board includes a first wiring board including a first insulating layer, a first conductor layer formed on the first insulating layer, and metal elements penetrating the first insulating layer and the first conductor layer such that the metal elements are electrically connected to each other by the first conductor layer, and a second wiring board including a second insulating layer and a second conductor layer formed on the second insulating layer and including metal connection terminals such that the metal connection terminals are corresponding to and directly bonded to the metal elements of the first wiring board, respectively.

According to another aspect of the present invention, a method for manufacturing a composite wiring board includes preparing a first wiring board including a first insulating layer, a first conductor layer formed on the first insulating layer, and metal elements penetrating the first insulating layer and the first conductor layer such that the metal elements are electrically connected to each other by the first conductor layer, preparing a second wiring board including a second insulating layer and a second conductor layer formed on the second insulating layer and including metal connection terminals such that the metal connection terminals are corresponding to the metal elements of the first wiring board, respectively, bringing welding tools of a resistance welding machine into contact with one-side surfaces of the metal elements of the first wiring board, respectively, while bringing other-side surfaces of the metal elements into contact with the metal connection terminals of the second wiring board, respectively, and applying current such that current flows between the welding tools, through the first conductor layer electrically connecting the metal elements and through the second conductor layer between the metal connection terminals in contact with the other-side surfaces of the metal elements and that the other-side surfaces of the metal elements are directly bonded to the metal connection terminals of the second wiring board by resistance welding.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a top view schematically illustrating a composite wiring board according to an embodiment of the present invention;

FIG. 1B is a cross-sectional view along a B-B′ line of FIG. 1A;

FIG. 2 is a cross-sectional view schematically illustrating a process in which a first wiring board and a second wiring board are bonded to each other by resistance welding;

FIG. 3A is a cross-sectional view schematically illustrating a composite wiring board according to another embodiment of the present invention;

FIG. 3B is a cross-sectional view schematically illustrating a process in which the composite wiring board illustrated in FIG. 3A is manufactured by directly bonding a first wiring board and a second wiring board to each other by resistance welding;

FIG. 4 is a top view schematically illustrating a composite wiring board according to another embodiment of the present invention;

FIG. 5 is a top view schematically illustrating a composite wiring board according to another embodiment of the present invention; and

FIG. 6A-6D are process diagrams schematically illustrating an example of a method for manufacturing a first wiring board.

### DETAILED DESCRIPTION OF THE EMBODIMENTS

The embodiments will now be described with reference to the accompanying drawings, wherein like reference numerals designate corresponding or identical elements throughout the various drawings.

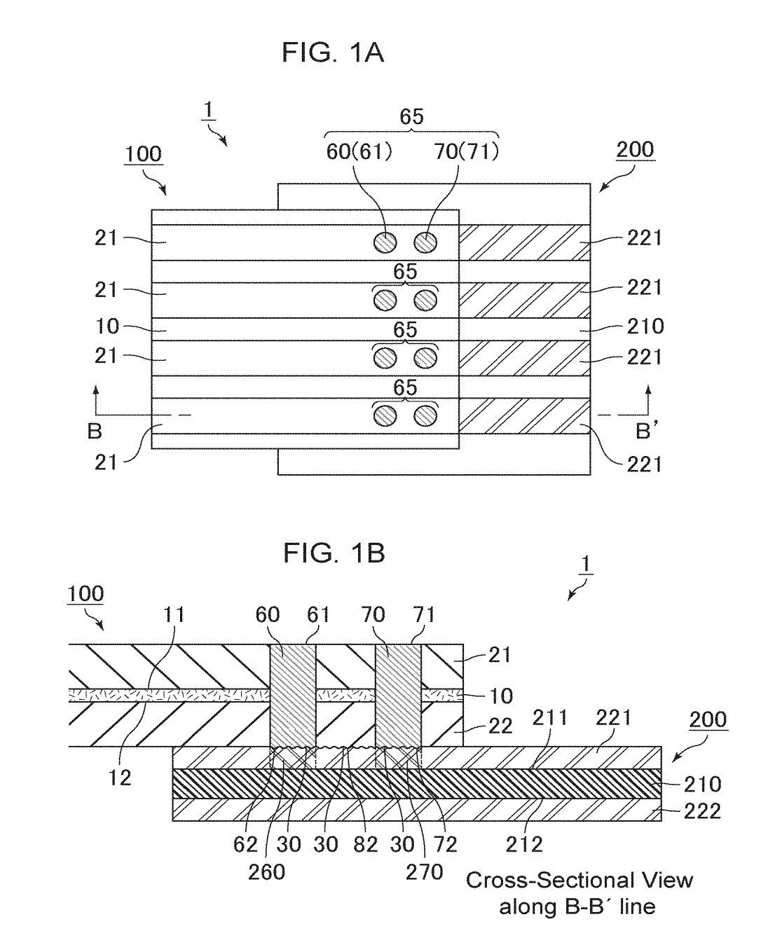

FIG. 1A is a top view schematically illustrating a composite wiring board according to an embodiment of the present invention. FIG. 1B is a cross-sectional view along a B-B′ line of FIG. 1A.

In the composite wiring board 1 illustrated in FIG. 1A, a first wiring board is a flexible wiring board 100; a first insulating layer is a flexible insulating layer 10; and two metal elements are a metal block 60 and a metal block 70. Further, a second wiring board is a rigid wiring board 200; and a second insulating layer is a rigid insulating layer 210.

In FIG. 1A, with respect to the flexible wiring board 100, the flexible insulating layer 10, the metal block 60 and the metal block 70, and a first conductor layer 21 that electrically connects the metal block 60 and the metal block 70 are indicated with reference numeral symbols. Further, with respect to the rigid wiring board 200, a second conductor layer 221 and the rigid insulating layer 210 are indicated with reference numeral symbols.

The metal block 60 and the metal block 70 are arrayed in a row and a metal element row 65 is formed.

In the flexible wiring board 100, four first conductor layers 21 each in a strip-like shape are provided. A metal element row 65 is provided in each first conductor layer 21. In FIG. 1A, a total of eight metal blocks as metal elements are illustrated. However, each two metal blocks are electrically connected to each other, but are not electrically connected to the other six metal blocks.

In the present specification, that “the first wiring board has two or more metal elements” means that there are two or more metal elements that are electrically connected to each other. Even when there are two or more metal elements that are not electrically connected in the first wiring board, it does not mean that “the first wiring board has two or more metal elements” in the present specification.

In the rigid wiring board 200, four second conductor layers 221 each in a strip-like shape are provided. The second conductor layers 221 respectively correspond to the four metal element rows 65 of the flexible wiring board 100. Further, corresponding to the four metal element rows 65 of the flexible wiring board 100, the second conductor layer 221 includes four rows of metal connection terminals (not illustrated in FIG. 1A).

FIG. 1B illustrates layer structures of the flexible wiring board 100 and the rigid wiring board 200.

The flexible wiring board 100 includes the flexible insulating layer 10 that has a first main surface 11 and a second main surface 12 (that is on an opposite side of the first main surface 11), the first conductor layer 21 that is formed on the first main surface 11 of the flexible insulating layer 10, and a third conductor layer 22 that is formed on the second main surface 12 of the flexible insulating layer 10.

The flexible wiring board 100 includes two or more holes 50 each of which penetrates the first conductor layer 21, the flexible insulating layer 10 and the third conductor layer 22, and the metal block 60 and the metal block 70 as the metal elements that are respectively inserted into the holes 50.

The metal block 60 and the metal block 70 are electrically connected to each other by the first conductor layer 21 in the flexible wiring board 100. Further, the metal block 60 and the metal block 70 are also electrically connected to each other by the third conductor layer 22 in the flexible wiring board 100.

The rigid wiring board 200 includes the rigid insulating layer 210 that has a first main surface 211 and a second main surface 212 (that is on an opposite side of the first main surface 211), the second conductor layer 221 that is formed on the first main surface 211 of the rigid insulating layer 210, and a fourth conductor layer 222 that is formed on the second main surface 212 of the rigid insulating layer 210.

The second conductor layer 221 includes a metal connection terminal 260 and a metal connection terminal 270 corresponding to the two or more metal elements of the first wiring board. The metal connection terminal 260 and the metal connection terminal 270 are each a portion of the second conductor layer 221.

The metal block 60 that is a metal element of the first wiring board and the metal connection terminal 260 of the second wiring board are directly bonded to each other, and the metal block 70 that is a metal element of the first wiring board and the metal connection terminal 270 of the second wiring board are directly bonded to each other.

The direct bonding is performed by resistance welding, and the metal block 60 and the metal block 70 are used as a base material for the resistance welding. A weld 30 (a portion indicated by a wavy line in FIG. 1B) is formed by the resistance welding. The entire surface (the other surface 62) of the metal block 60 and the entire surface (the other surface 72) of the metal block 70 both become the weld 30.

Further, a surface 82 of the third conductor layer 22 that electrically connect the metal block 60 and the metal block 70 to each other may also become the weld 30.

When the metal elements of the first wiring board and the metal connection terminals of the second wiring board are directly bonded to each other by the resistance welding, the first wiring board and the second wiring board are connected to each other with strong bonding. Further, an increase in electrical resistance at the weld, which is a connecting part of the first wiring board and the second wiring board, does not occur.

When a composite wiring board according to an embodiment of the present invention is a composite wiring board that includes a rigid wiring board and a flexible wiring board, it is preferable that the first wiring board is the flexible wiring board and the second wiring board be the rigid wiring board. Since it is easier for the metal elements to be formed in the flexible wiring board, the flexible wiring board is more suitable to be used as the first wiring board.

When the first wiring board is the flexible wiring board, the first insulating layer is formed of a flexible insulating layer.

The flexible insulating layer is preferably formed of an insulating resin. Examples of a material that forms the insulating resin include polyimide, glass epoxy, and the like. Among these materials, polyimide is preferred. When the insulating resin is polyimide, the insulating resin is both flexible and insulating. Therefore, a shape can be deformed according to an intended use, while sufficient insulation is ensured.

A thickness of the flexible insulating layer is not particularly limited. However, it is preferable that the thickness of the flexible insulating layer be 30-70 μm. When the thickness of the flexible insulating layer is smaller than 30 μm, the flexible insulating layer easily bends, and further, the substrate easily bends. Therefore, bonding of the flexible insulating layer with a wiring or another member can be easily broken. On the other hand, when the thickness of the flexible insulating layer is larger than 70 μm, when a hole is formed by punching in order to provide a metal part, a crack is likely to occur around the hole and reliability may decrease.

A conductor layer is formed on at least one side of the flexible insulating layer. FIG. 1B illustrates an example in which conductor layers (the first conductor layer and the third conductor layer) are respectively formed on both sides of the flexible insulating layer.

A material that forms a conductor layer is not particularly limited. However, it is preferable that the material be copper, nickel or the like.

These materials have good electrical conductivity and can be suitably used as conductors.

Thicknesses of the first conductor layer and the third conductor layer are not particularly limited. However, it is preferable that the first conductor layer and the third conductor layer be each thicker than the flexible insulating layer. Further, it is preferable that the thicknesses of the first conductor layer and the third conductor layer be each 10-300 μm. When the thicknesses of the first conductor layer and the third conductor layer are each smaller than 10 μm, during handling, the conductor layers are easily broken and a failure rate increases. On the other hand, when the thicknesses of the first conductor layer and the third conductor layer are each greater than 300 μm, when the flexible wiring board is bent and used, due to the bending, a compressive stress applied from the conductor layers to the flexible insulating layer is large and thus the flexible insulating layer is easily broken.

The metal elements each penetrate the first conductor layer, the first insulating layer and the third conductor layer, and are used as a base material for the resistance welding. A material of the metal elements is not particularly limited. However, it is preferable that the material be copper that is excellent in electrical conductivity and thermal conductivity. Further, the metal elements are preferably metal blocks, and more preferably copper blocks. It is preferable that the metal elements be respectively inserted in holes that are each provided so as to penetrate the first wiring board. Metal blocks that are respectively inserted in the holes become the metal elements each of which penetrates the first insulating layer and the conductor layers.

The metal blocks are each suitable for flowing a large current, and are suitable for welding to metal connection terminals as compared to a case of structures such as through holes or bottomed filled vias that can be considered as structure of metal elements.

Further, different from filled vias that are respectively formed in through holes through a chemical process such as plating, metal blocks do not have voids formed therein and do not have concave or convex portions or the like on surfaces thereof. Since there are no voids formed inside the metal blocks, heat-transfer efficiency of the metal blocks is not reduced, and heat dissipation performance of the metal blocks can be ensured. Further, the metal blocks are also preferable in that conductor volumes of the metal blocks can be easily increased as compared to filled vias.

Further, a shape of each of the metal blocks is not particularly limited. However, it is preferable that the shape of each of the metal blocks be a columnar shape having a flat bottom surface (front surface). Examples of such a shape include shapes of a circular column, a quadrangular column, a hexagonal column, an octagonal column, and the like.

The metal elements are used as a base material for resistance welding to the metal connection terminals of the second wiring board. Specifically, surfaces of the metal elements are exposed on a main surface of the first wiring board and can be used as welds that allow resistance welding to be performed. It is possible to have an embodiment in which only one of the surfaces of each of the metal elements positioned at one of the two main surfaces of the first wiring board can be used as a weld. It is also possible to have an embodiment in which the surfaces of each of the metal elements that are respectively positioned at the two main surfaces of the first wiring board can be used as welds.

Further, it is preferable that the metal elements be formed from a base material for resistance welding.

In order to resistively weld a metal element to a metal connection terminal of the second wiring board, a welding tool of a resistance welding machine as an electrode is brought into contact with one surface of the metal part, and the metal connection terminal is brought into contact with the other surface of the metal part.

Then, when a current is caused to flow from the welding tool that is in contact with one surface of the metal part, heat is generated between the other surface of the metal element and the metal connection terminal of the second wiring board, and thus resistance welding can be performed.

Since two or more metal elements are provided, the first wiring board and the second wiring board can be connected to each other by multi-terminal connection. As will be described later, the metal elements can be manufactured by forming holes in the first wiring board and inserting metal blocks into the holes. Therefore, a large number of metal elements can be provided in the first wiring board without having to individually and separately prepare the metal elements. Then, by using the first wiring board in which a large number of metal elements are provided, the multi-terminal connection with the second wiring board can be easily performed.

A process in which the resistance welding is performed will be described in detail later.

In a composite wiring board according to an embodiment of the present invention, it is preferable that the metal elements each have a cross-sectional area of 0.05-4 mm². The cross-sectional area of each of the metal elements is an area of the surface of each the metal elements when the composite wiring board is viewed from above.

When the cross-sectional area of each of the metal elements is 0.05 mm² or more, resistance of each metal element itself is sufficiently small, and thus the metal elements can each be prevented from being melted by the current that is caused to flow for resistance welding. On the other hand, a large metal element having a cross-sectional area exceeding 4 mm² is usually not required.

Further, for the two or more metal elements, it is preferable that a distance between adjacent metal elements be 3 mm or less. Further, it is preferable that the distance between adjacent metal elements be 0.3 mm or more.

As the rigid insulating layer, which is the second insulating layer that forms the rigid wiring board, an insulating layer used in an ordinary rigid wiring board can be used. As a resin material, an epoxy resin, a bismaleimide-triazine resin, a phenol resin or the like can be used. Further, the rigid insulating layer may be an insulating layer in which glass fiber or the like is combined with these resins.

A conductor layer is formed on at least one side of the second wiring board. FIG. 1B illustrates an example in which conductor layers (the second conductor layer and the fourth conductor layer) are respectively forming on both sides of the second insulating layer.

A material that forms a conductor layer is not particularly limited. However, it is preferable that the material be copper, nickel or the like.

These materials have good electrical conductivity and can be suitably used as conductors.

The second conductor layer includes the metal connection terminals corresponding to the two or more metal elements of the first wiring board. The metal connection terminals are preferably portions of a conductor pattern obtained by patterning the second conductor layer, and are respectively formed at positions where the metal elements are respectively bonded. Further, when the resistance welding is performed, current flows between the two or more metal connection terminals.

A material of the metal connection terminals is not particularly limited as long as the material can be resistance welded to the metal elements of the first wiring board, and is preferably a material that can be resistance welded to copper, which is a preferred material for metal elements of a flexible wiring board. For example, copper, stainless steel, nickel, and the like can be used.

The term “direct bonding” in the composite wiring board according to an embodiment of the present invention means that the metal elements of the first wiring board and the metal connection tei ninals of the second wiring board are bonded to each other without using other members such as solders. Specifically, it is preferable that the metal elements of the flexible wiring board and the metal connection terminals of the rigid wiring board be resistance welded to each other.

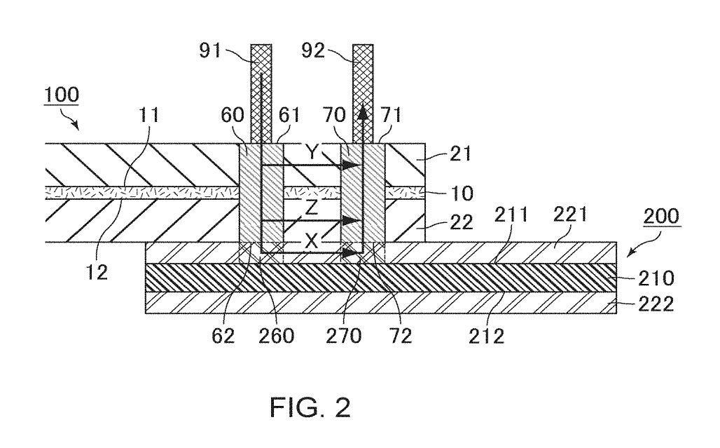

FIG. 2 is a cross-sectional view schematically illustrating a process in which the first wiring board and the second wiring board are bonded to each other by resistance welding. FIG. 2 schematically illustrates how resistance welding is performed in the state illustrated in FIG. 1B.

FIG. 2 schematically illustrates a state in which resistance welding is performed by bringing a welding tool 91 and a welding tool 92 of a resistance welding machine into contact with the metal block 60 and the metal block 70, which are the metal elements of the flexible wiring board 100.

In FIG. 2, the welding tool 91 of the resistance welding machine is in contact with one surface 61 of the metal block 60 and the welding tool 92 of the resistance welding machine is in contact with one surface 71 of the metal block 70. Further, the other surface 62 of the metal block 60 is in contact with the metal connection terminal 260 of the rigid wiring board 200, and the other surface 72 of the metal block 70 is in contact with the metal connection terminal 270 of the rigid wiring board 200.

When a current is caused to flow between the welding tool 91 and the welding tool 92, heat is generated due to interface resistance between the other surface 62 of the metal block 60 and the metal connection terminal 260, and resistance welding is performed between the other surface 62 of the metal block 60 and the metal connection terminal 260. Heat is generated due to interface resistance between the other surface 72 of the metal block 70 and the metal connection terminal 270, and resistance welding is performed between the other surface 72 of the metal block 70 and the metal connection terminal 270. As a result, the composite wiring board 1 is manufactured in which the flexible wiring board 100 and the rigid wiring board 200 are bonded to each other by the resistance welding.

When a current is caused to flow between the welding tool 91 and the welding tool 92, the current is thought to flow through three paths indicated by an arrow (X), an arrow (Y) and an arrow (Z) in FIG. 2.

The path indicated by the arrow (X) (hereinafter, also referred to as a path (X)) passes through between the other surface 62 of the metal block 60 and the metal connection terminal 260, passes through the second conductor layer 221 between the metal connection terminal 260 and the metal connection terminal 270, and passes through between the metal connection terminal 270 and the other surface 72 of the metal block 70. A current flowing through the path (X) is a current that contributes to the resistance welding.

The path indicated by the arrow (Y) (hereinafter, also referred to as a path (Y)) passes through the first conductor layer 21 between the metal block 60 and the metal block 70.

The path indicated by the arrow (Z) (hereinafter, also referred to as a path (Z)) passes through the third conductor layer 22 between the metal block 60 and the metal block 70.

In a composite wiring board according to an embodiment of the present invention, in addition to the path (the path (X) in FIG. 2) through which the current that contributes to the resistance welding flows, paths (the path (Y) and the path (Z) in FIG. 2) through each of which a current can flow are provided. Therefore, a current flowing through the path through which a current contributing to the resistance welding flows is prevented from becoming too large, so it is possible to prevent occurrence of meltdown in the second conductor layer on the second wiring board side.

In order to prevent occurrence of meltdown in the second conductor layer on the second wiring board side, in addition to a path through which a current contributing to the resistance welding flows, it is sufficient to provide at least one path through which a current can flow. Therefore, it is sufficient that the first conductor layer that is formed on at least one side of the first insulating layer and electrically connects the two or more metal elements is provided and the first conductor layer forms a path through which a current can flow. The first conductor layer may be formed on either side of the first insulating layer as long as the two or more metal elements can be electrically connected in the first wiring board. Therefore, a conductor layer formed at the position of the third conductor layer 22 illustrated in FIG. 2 can also regarded as the first conductor layer.

Further, it is preferable that the third conductor layer be further provided on the other side of the first insulating layer, that is, on the opposite side of the surface on which the first conductor layer is formed, and the third conductor layer electrically connect the two or more metal elements in the first wiring board. In this embodiment, in addition to the path through which the current contributing the resistance welding flows, two passes through each of which a current can flow are provided. Therefore, occurrence of meltdown in the second conductor layer on the second wiring board side can be more reliably prevented and thus this embodiment is preferable. The composite wiring board illustrated in FIG. 1B is this embodiment.

Further, in the composite wiring board 1 illustrated in FIG. 1B, the conductor layer forming on the first main surface 11 side of the flexible insulating layer 10 is the first conductor layer 21 and the conductor layer formed on the second main surface 12 side of the flexible insulating layer 10 is the third conductor layer 22. However, it is arbitrary to regard a conductor layer formed on either side as the first conductor layer 21 or the third conductor layer 23. Therefore, it is also possible that the conductor layer formed on the first main surface 11 side of the flexible insulating layer 10 is regarded as the third conductor layer, and the conductor layer formed on the second main surface 12 side of the flexible insulating layer 10 is regarded as the first conductor layer.

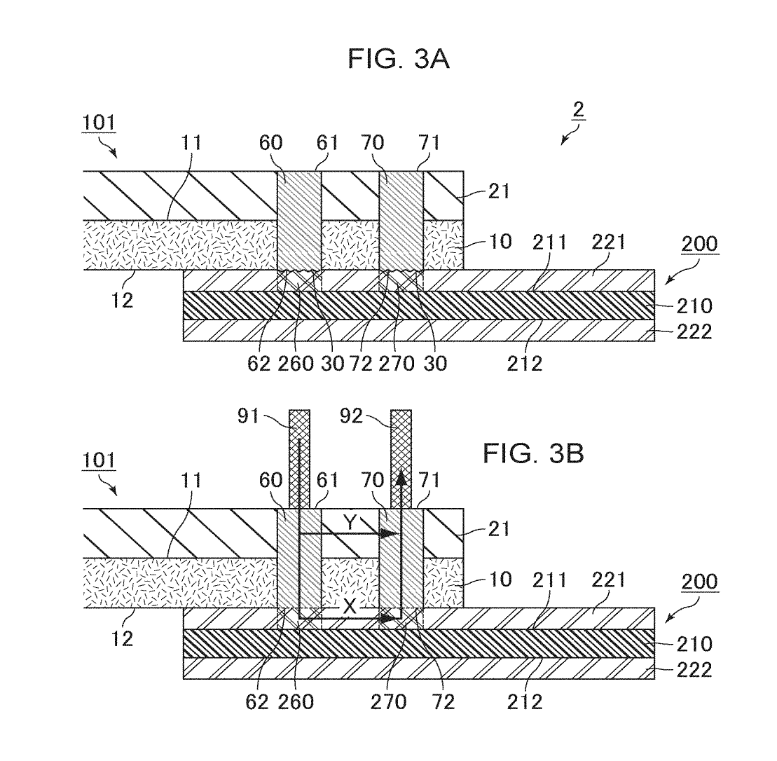

FIG. 3A is a cross-sectional view schematically illustrating a composite wiring board according to another embodiment of the present invention. FIG. 3B is a cross-sectional view schematically illustrating a process in which the composite wiring board illustrated in FIG. 3A is manufactured by directly bonding a first wiring board and a second wiring board to each other by resistance welding.

In a composite wiring board 2 illustrated in FIG. 3A, as the first wiring board, a flexible wiring board 101 having a structure different from the flexible wiring board 100 illustrated in FIG. 1B is provided.

The flexible wiring board 101 is different from the flexible wiring board 100 illustrated in FIG. 1B in that, although the first conductor layer 21 is formed on the first main surface 11 of the flexible insulating layer 10, a conductor layer (the third conductor layer) is not formed on the second main surface 12 of the flexible insulating layer 10.

The flexible wiring board 101 includes two or more holes 50 each of which penetrates the first conductor layer 21 and the flexible insulating layer 10, and a metal block 60 and a metal block 70 as metal elements that are respectively inserted into the holes 50. Other parts of the structure of the flexible wiring board 101 are the same as the flexible wiring board 100 illustrated in FIG. 1B.

A rigid wiring board 200 as the second wiring board has the same structure as the rigid wiring board 200 illustrated in FIG. 1B.

FIG. 3B schematically illustrates a state in which resistance welding is performed by bringing a welding tool 91 and a welding tool 92 of a resistance welding machine into contact with the metal block 60 and the metal block 70, which are the metal elements of the flexible wiring board 101.

When a current is caused to flow between the welding tool 91 and the welding tool 92, the current is thought to flow through two paths indicated by an arrow (X) and an arrow (Y) in FIG. 3B.

The path indicated by the arrow (X) (hereinafter, also referred to as a path (X)) passes through between the other surface 62 of the metal block 60 and the metal connection terminal 260, passes through the second conductor layer 221 between the metal connection terminal 260 and the metal connection terminal 270, and passes through between the metal connection terminal 270 and the other surface 72 of the metal block 70. A current flowing through the path (X) is a current that contributes to the resistance welding.

The path indicated by the arrow (Y) (hereinafter, also referred to as a path (Y)) passes through the first conductor layer 21 between the metal block 60 and the metal block 70.

Also in this embodiment, in addition to the path (the path (X) in FIG. 3B) through which the current contributing to the resistance welding flows, a path (the path (Y) in FIG. 3B) through which a current can flow is provided. Therefore, a current flowing through the path through which a current contributing to the resistance welding flows is prevented from becoming too large, so it is possible to prevent occurrence of meltdown in the second conductor layer on the second wiring board side.

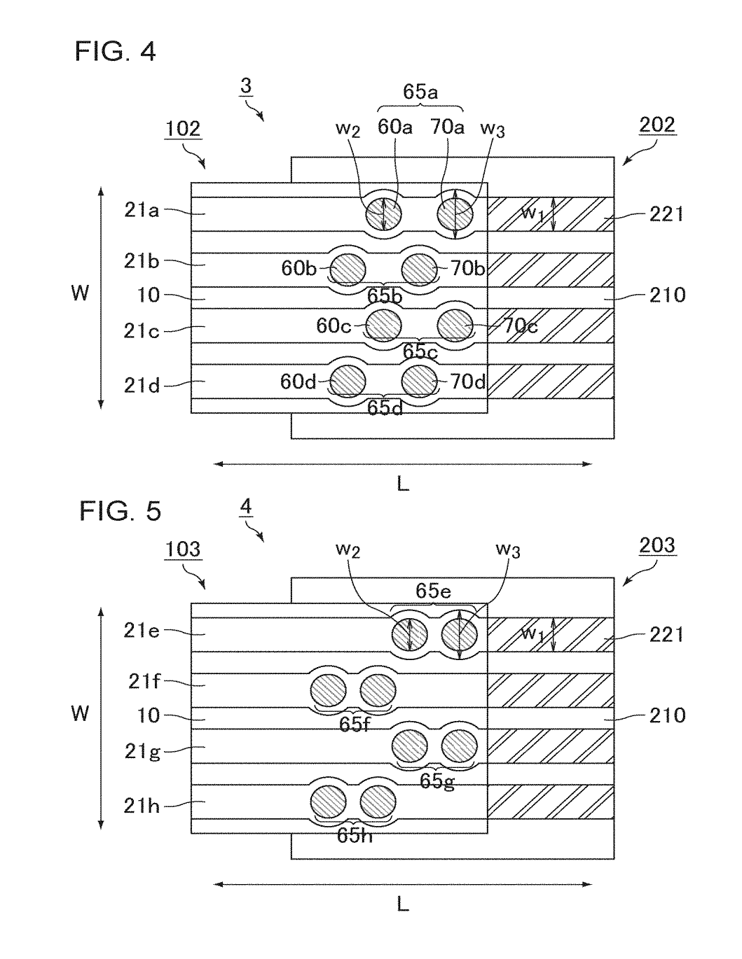

FIG. 4 is a top view schematically illustrating a composite wiring board according to another embodiment of the present invention.

In a composite wiring board 3 illustrated in FIG. 4, a flexible wiring board 102 has four metal element rows.

A rigid wiring board 202 includes four second conductor layers 221 and four rows of metal connection terminals corresponding to the four metal element rows.

Although not illustrated in FIG. 4, the metal connection terminals each have a circular shape that is slightly larger than a circle illustrating an upper surface shape of each of the metal blocks and has a width indicated by a double-headed arrow (W3) in FIG. 4.

In a width direction of the flexible wiring board 102 (a direction indicated by a double-headed arrow (W) in FIG. 4), each metal element is positioned so as to be staggered with respect to metal elements in adjacent metal element rows.

This is specifically described below.

In the flexible wiring board 102, four first conductor layers 21 each in a strip-like shape are provided, and a metal element row is provided in each of the first conductor layers 21. That is, a metal element row (65a), a metal element row (65b), a metal element row (65c) and a metal element row (65d) are respectively provided in a first conductor layer (21a), a first conductor layer (21b), a first conductor layer (21c) and a first conductor layer (21d).

When focusing on a metal block (60a) and a metal block (70a) that for ii the metal element row (65a), positions of a metal block (60b) and a metal block (70b) that form the adjacent metal element row (65b) are both shifted in a length direction (indicated by a double-headed arrow (L) in FIG. 4) of the flexible wiring board.

A metal block (60c) and a metal block (70c) that form the metal element row (65c), and a metal block (60d) and a metal block (70d) that form the metal element row (65d), are similarly arrayed.

By arraying the metal element rows in this way, a width (indicated by a double-headed arrow (W2) in FIG. 4) of each of the metal elements (metal blocks) can be equal to or larger than a width (indicated by a double-headed arrow (W1) in FIG. 4) of each of the second conductor layers. Further, the width (indicated by the double-headed arrow (W3) in FIG. 4) of each of the metal connection terminals can be larger than the width (indicated by the double-headed arrow (W1) in FIG. 4) of each of the second conductor layers. Then, since a bonding area between the metal elements and the metal connection terminals can be increased, bonding strength between the metal elements and the metal connection terminals can be increased.

FIG. 5 is a top view schematically illustrating a composite wiring board according to another embodiment of the present invention.

In a composite wiring board 4 illustrated in FIG. 5, a flexible wiring board 103 has four metal element rows.

A rigid wiring board 203 includes four second conductor layers 221 and four rows of metal connection terminals corresponding to the four metal element rows.

Although not illustrated in FIG. 5, the metal connection terminals each have a circular shape that is slightly larger than a circle illustrating an upper surface shape of each of the metal blocks and has a width indicated by a double-headed arrow (W3) in FIG. 5.

In a width direction of the flexible wiring board 103 (a direction indicated by a double-headed arrow (W) in FIG. 5), each entire metal element row is positioned so as to be staggered with respect to each entire adjacent metal element row.

This is specifically described below.

In the flexible wiring board 103, four first conductor layers 21 each in a strip-like shape are provided, and a metal element row is provided in each of the first conductor layers 21. That is, a metal element row (65e), a metal element row (65f), a metal element row (65g) and a metal element row (65h) are respectively provided in a first conductor layer (21e), a first conductor layer (21f), a first conductor layer (21g) and a first conductor layer (21h).

When focusing on the metal element row (65f), positions of the metal element row (65e) and the metal element row (65g) that are respectively adjacent to the metal element row (65f) on upper and lower sides are entirely shifted in a length direction (indicated by a double-headed arrow (L) in FIG. 5) of the flexible wiring board. The metal element row (65e), the metal element row (65g) and the metal element row (65h) are also each entirely shifted with respect to adjacent metal element rows in the length direction of the flexible wiring board. That is, the metal element row (65e), the metal element row (65f), the metal element row (65g) and the metal element row (65h) are arrayed so as to be staggered with respect to each other.

By arraying the metal element rows in this way, a width (indicated by a double-headed arrow (W2) in FIG. 5) of each of the metal elements (metal blocks) can be equal to or larger than a width (indicated by a double-headed arrow (W1) in FIG. 5) of each of the second conductor layers. Further, the width (indicated by the double-headed arrow (W3) in FIG. 5) of each of the metal connection terminals can be larger than the width (indicated by the double-headed arrow (W1) in FIG. 5) of each of the second conductor layers. Then, since a bonding area between the metal elements and the metal connection terminals can be increased, bonding strength between the metal elements and the metal connection terminals can be increased.

In the following, a method for manufacturing a first wiring board that forms a composite wiring board according to an embodiment of the present invention is described.

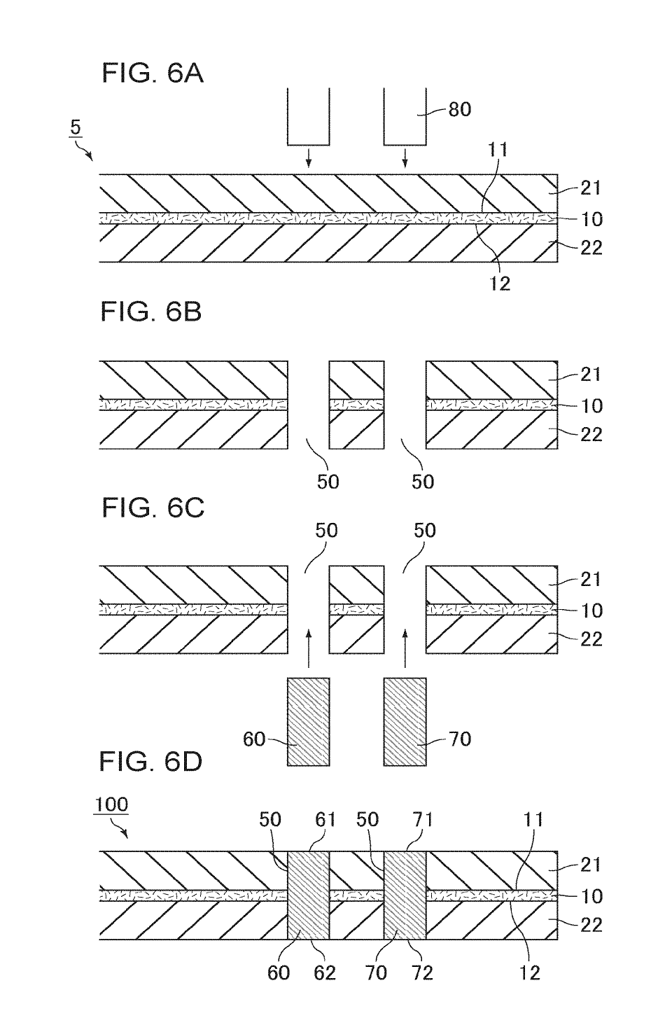

FIG. 6A-6D are process diagrams schematically illustrating an example of a method for manufacturing the first wiring board.

(1) Conductor Substrate Preparation Process

First, as a conductor substrate preparation process, a conductor substrate is prepared in which a conductor layer is formed on at least one side of a flexible insulating layer. The conductor layer becomes a first conductor layer and/or a third conductor layer.

FIG. 6A illustrates a process in which a double-sided conductor substrate 5 is prepared in which a first conductor layer 21 is formed on a first main surface 11 of a flexible insulating layer 10 and a third conductor layer 22 is formed on a second main surface 12 of the flexible insulating layer 10, the flexible insulating layer 10 being formed from an insulating resin and having the first main surface 11 and the second main surface 12 that is on an opposite side of the first main surface 11.

Materials that form the flexible insulating layer 10, the first conductor layer 21 and the third conductor layer 22 are the same as those described in the description of the composite wiring board and thus a description thereof is omitted.

(2) Hole Formation Process

Next, holes 50 that penetrate the first conductor layer 21, the flexible insulating layer 10 and the third conductor layer 22 are formed.

It is preferable that the holes be formed by punching. FIG. 6A illustrates a state in which a punch 80 that is used in punching is positioned on the first conductor layer 21 side.

FIG. 6B illustrates the double-sided conductor substrate in which the holes 50 are formed.

(3) Metal Block Insertion Process

Next, by respectively inserting metal blocks into the holes, metal elements penetrating the flexible insulating layer and the conductor layers are formed. It is preferable that the insertion of the metal blocks be performed from a side opposite to a side where the punching is performed.

FIG. 6C illustrates an example in which a metal block 60 and a metal block 70 are respectively inserted into the holes 50 from the third conductor layer 22 side.

Further, when necessary, it is preferable to perform pattern formation with respect to the conductor layers to form necessary wirings. Further, it is preferable to perform coining to improve flatness of surfaces of the metal blocks.

By the above-described processes, the flexible wiring board 100 illustrated in FIG. 6D can be manufactured.

As the second wiring board, a rigid wiring board manufactured by a known method for manufacturing a rigid wiring board may be used. By directly bonding the first wiring board prepared as described above and the second wiring board by resistance welding, the composite wiring board can be manufactured.

When an anisotropic conductive film is used to connect the rigid wiring board and the flexible wiring board, there is a problem that peel strength is insufficient and electrical resistance at a connecting part increases.

A composite wiring board according to an embodiment of the present invention has a structure in which two wiring boards are connected to each other with strong bonding and electrical resistance at a connecting part is low.

A composite wiring board according to an embodiment of the present invention includes a first wiring board and a second wiring board. The first wiring board includes a first insulating layer, a first conductor layer that is formed on at least one side of the first insulating layer, and two or more metal elements penetrating the first insulating layer and the first conductor layer. The two or more metal elements are electrically connected to each other by the first conductor layer. The second wiring board includes a second insulating layer and a second conductor layer that is formed on at least one side of the second insulating layer. The second conductor layer includes metal connection terminals corresponding to the two or more metal elements of the first wiring board. The metal elements of the first wiring board and the metal connection terminals of the second wiring board are respectively directly bonded to each other.

A method for manufacturing a composite wiring board according to an embodiment of the present invention includes: a process in which a first wiring board and a second wiring board are respectively prepared, the first wiring board including a first insulating layer, a first conductor layer that is formed on at least one side of the first insulating layer, and two or more metal elements penetrating the first insulating layer and the first conductor layer, the two or more metal elements being electrically connected to each other by the first conductor layer, the second wiring board including a second insulating layer and a second conductor layer that is formed on at least one side of the second insulating layer, and the second conductor layer including metal connection terminals corresponding to the two or more metal elements of the first wiring board; and a process in which welding tools of a resistance welding machine are respectively brought into contact with one-side surfaces of the two or more metal elements of the first wiring board, other-side surfaces of the metal elements are brought into contact with the metal connection terminals of the second wiring board, and the other-side surfaces of the metal elements are respectively directly bonded to the metal connection terminals of the second wiring board by resistance welding by causing a current to flow between the welding tools so that a current flows through the first conductor layer that electrically connects between the two or more metal elements and a current flows through the second conductor layer between the metal connection terminals that are respectively in contact with the other-side surfaces of the two or more metal part.

Obviously, numerous modifications and variations of the present invention are possible in light of the above teachings. It is therefore to be understood that within the scope of the appended claims, the invention may be practiced otherwise than as specifically described herein.

1. A composite wiring board, comprising:
a first wiring board comprising a first insulating layer, a first conductor layer formed on the first insulating layer, and a plurality of metal elements penetrating the first insulating layer and the first conductor layer such that the plurality of metal elements is electrically connected to each other by the first conductor layer; and
a second wiring board comprising a second insulating layer and a second conductor layer formed on the second insulating layer and including a plurality of metal connection terminals such that the plurality of metal connection terminals is corresponding to and directly bonded to the metal elements of the first wiring board, respectively.

2. A composite wiring board according to claim 1, wherein the first wiring board comprises the first conductor layer on one side of the first insulating layer and a third conductor layer on an opposite side of the first insulating layer with respect to the first conductor layer such that the plurality of metal elements is electrically connected to each other by the third conductor layer.

3. A composite wiring board according to claim 1, wherein the plurality of metal elements is formed such that each of the metal elements has a cross-sectional area in a range of 0.05 to 4 mm².

4. A composite wiring board according to claim 1, wherein the plurality of metal elements comprises a plurality of metal blocks.

5. A composite wiring board according to claim 1, wherein the first wiring board is a flexible wiring board, and the second wiring board is a rigid wiring board.

6. A composite wiring board according to claim 1, wherein the plurality of metal elements is formed such that a distance between adjacent metal elements is 3 mm or less.

7. A composite wiring board according to claim 1, wherein the first wiring board is formed such that the plurality of metal elements is arrayed in a plurality of metal element rows and each of the metal element rows has at least two metal elements, and the second wiring board is forming such that the second conductor layer and plurality of metal connection terminals are arrayed in a plurality of rows to correspond to the metal element rows of the first wiring board.

8. A composite wiring board according to claim 7, wherein the plurality of metal elements is arrayed in the plurality of metal element rows such that the metal elements in a metal element row are staggered with respect to the metal elements in an adjacent metal element row in a width direction of the first wiring board.

9. A composite wiring board according to claim 7, wherein the plurality of metal element rows is formed such that each of the metal element rows is staggered with respect to an adjacent metal element row in a width direction of the first wiring board.

10. A composite wiring board according to claim 8, wherein the plurality of metal elements is formed such that each of the metal element has a width which is greater than a width of the second conductor layer in each of the rows, and the plurality of metal connection terminals is formed such that each of the metal connection terminals has a width which is greater than the width of the second conductor layer in each of the rows.

11. A composite wiring board according to claim 9, wherein the plurality of metal elements is formed such that each of the metal element has a width which is greater than a width of the second conductor layer in each of the rows, and the plurality of metal connection terminals is formed such that each of the metal connection terminals has a width which is greater than the width of the second conductor layer in each of the rows.

12. A composite wiring board according to claim 2, wherein the plurality of metal elements is formed such that each of the metal elements has a cross-sectional area in a range of 0.05 to 4 mm².

13. A composite wiring board according to claim 2, wherein the plurality of metal elements comprises a plurality of metal blocks.

14. A composite wiring board according to claim 2, wherein the first wiring board is a flexible wiring board, and the second wiring board is a rigid wiring board.

15. A composite wiring board according to claim 2, wherein the plurality of metal elements is formed such that a distance between adjacent metal elements is 3 mm or less.

16. A composite wiring board according to claim 2, wherein the first wiring board is formed such that the plurality of metal elements is arrayed in a plurality of metal element rows and each of the metal element rows has at least two metal elements, and the second wiring board is formed such that the second conductor layer and plurality of metal connection terminals are arrayed in a plurality of rows to correspond to the metal element rows of the first wiring board.

17. A composite wiring board according to claim 16, wherein the plurality of metal elements is arrayed in the plurality of metal element rows such that the metal elements in a metal element row are staggered with respect to the metal elements in an adjacent metal element row in a width direction of the first wiring board.

18. A composite wiring board according to claim 16, wherein the plurality of metal element rows is formed such that each of the metal element rows is staggered with respect to an adjacent metal element row in a width direction of the first wiring board.

19. A method for manufacturing a composite wiring board, comprising:
preparing a first wiring board comprising a first insulating layer, a first conductor layer formed on the first insulating layer, and a plurality of metal elements penetrating the first insulating layer and the first conductor layer such that the plurality of metal elements is electrically connected to each other by the first conductor layer;
preparing a second wiring board comprising a second insulating layer and a second conductor layer formed on the second insulating layer and including a plurality of metal connection terminals such that the plurality of metal connection terminals is corresponding to the metal elements of the first wiring board, respectively;
bringing a plurality of welding tools of a resistance welding machine into contact with one-side surfaces of the metal elements of the first wiring board, respectively, while bringing other-side surfaces of the metal elements into contact with the metal connection terminals of the second wiring board, respectively; and
applying current such that current flows between the welding tools, through the first conductor layer electrically connecting the metal elements and through the second conductor layer between the metal connection terminals in contact with the other-side surfaces of the metal elements and that the other-side surfaces of the metal elements are directly bonded to the metal connection terminals of the second wiring board by resistance welding.

20. A method for manufacturing a composite wiring board according to claim 19, wherein the preparing of the first wiring board comprises preparing the first wiring board comprising the first conductor layer on one side of the first insulating layer and a third conductor layer on an opposite side of the first insulating layer with respect to the first conductor layer, and the applying of the current comprises applying the current such that the current flows through the third conductor layer electrically connecting the plurality of metal elements each other.
